(19) United States
(12) Patent Application Publication
(10) Pub. No.: US 2012/0111611 A1
(43) Pub. Date: May 10, 2012

(54) Printed circuit board and method of manufacturing the same

(75) Inventor: Jee Soo Mok, Yongin-si (KR)

(73) Assignee: SAMSUNG ELECTRO-MECHANICS CO., LTD., Suwon (KR)

(21) Appl. No.: 13/064,385

(22) Filed: Mar. 22, 2011

(30) Foreign Application Priority Data
Nov. 10, 2010 (KR) 10-2010-0111556

(51) Int. Cl. H05K 7/20; H05K 3/00; H05K 1/00

(52) U.S. Cl. 174/252; 174/250; 29/829

(57) ABSTRACT

Disclosed herein are a method of manufacturing a printed circuit board, including: providing a base substrate including a conductive layer provided on at least one surface thereof; forming conductive resist patterns by printing a conductive paste on the conductive layer; forming circuit wirings by etching the conductive layer using the conductive resist patterns as an etching mask; and forming a solder resist on the circuit wiring, and a printed circuit board manufactured therefrom.

### CROSS REFERENCE(S) TO RELATED APPLICATIONS

This application claims the benefit under 35 U.S.C. Section 119 of Korean Patent Application No. 10-2010-0111556, entitled “Printed Circuit Board and Method of Manufacturing the Same” filed on Nov. 10, 2010, which is hereby incorporated by reference in its entirety into this application.

### BACKGROUND OF THE INVENTION

1. Technical Field

The present invention relates to a printed circuit board and a method of manufacturing the same, and more particularly, to a printed circuit board using a conductive resist pattern formed by printing a conductive paste as an etching mask and a method of manufacturing the same.

2. Description of the Related Art

A printed circuit board, which is formed as a substrate including a circuit wiring, electrically interconnects various electronic components through the circuit wiring and supports the electronic components.

In order to manufacture the printed circuit board, after a dry film is first formed on a copper foil, exposure and development processes are performed on the dry film to form dry patterns. The copper foil layer is etched using the dry patterns as an etching mask to form the circuit wiring. Herein, the etching process of the copper foil layer for forming the circuit wiring may be a wet etching.

In accordance with the recent trend of compactness and multi-function in electronic products, the circuit wiring has been finely formed and a space width between the circuit wirings has also been narrowed due to a narrow wiring width. As a result, it is difficult to penetrate etchant to the copper foil layer under the dry patterns in the etching process of the copper foil layer to cause an etching defect, thereby having a limitation in implementing fine wiring patterns.

In order to solve this problem, there has been an attempt to reduce a thickness of the dry film to easily penetrate the etchant to the copper foil layer under the dry patterns. However, as the thickness of the dry film is reduced, a defect of tenting for protecting a via-hole for an interlayer connection or a defect of step coverage in a concave and convex substrate may occur. In order to prevent these defects, an expensive dry film is used.

### SUMMARY OF THE INVENTION

An object of the present invention is to provide a printed circuit board capable of reducing a manufacturing cost of the printed circuit board and implementing a fine circuit wiring pattern by using a conductive resist pattern formed by printing a conductive paste as an etching mask and a method of manufacturing the same.

According to an exemplary embodiment of the present invention, there is provided a method of manufacturing a printed circuit board, including: providing a base substrate including a conductive layer provided on at least one surface thereof; forming conductive resist patterns by printing a conductive paste on the conductive layer; forming circuit wirings by etching the conductive layer using the conductive resist patterns as an etching mask; and forming a solder resist on the circuit wiring.

The base substrate may include a heat radiating layer; an insulting layer disposed on the heat radiating layer; and a conductive layer disposed on the insulating layer.

The heat radiating layer may be made of a metal and the insulating layer may be made of a metal oxide.

The method of manufacturing a printed circuit board may further include interposing an adhesive layer between the insulating layer and the conductive layer.

The conductive paste may have a different etching selectivity from that of the conductive layer.

The conductive resist pattern may be made of a silver (Ag) paste.

The conductive resist pattern may be formed at a thickness in the range of 3 μm to 15 μm.

According to another exemplary embodiment of the present invention, there is a printed circuit board, including: circuit wirings formed on a base substrate; conductive resist patterns disposed on the circuit wirings; and a solder resist disposed on the base substrate including the conductive resist patterns.

The base substrate may include a heat radiating layer; and an insulating layer disposed on the heat radiating layer.

The printed circuit board according to claim 9 may further include an adhesive layer interposed between the insulating layer and the circuit wiring.

The heat radiating layer may be made of a metal and the insulating layer may be made of a metal oxide.

The conductive resist pattern may be made of a silver (Ag) paste.

### BRIEF DESCRIPTION OF THE DRAWINGS

FIGS. 1 to 4 are cross sectional views for explaining a process of manufacturing a printed circuit board according to an exemplary embodiment of the present invention.

### DESCRIPTION OF THE PREFERRED EMBODIMENTS

Hereinafter, the exemplary embodiments of the present invention will be described in detail with reference to the drawings of a printed circuit board. The exemplary embodiments of the present invention to be described below are provided by way of example so that the idea of the present invention can be sufficiently transferred to those skilled in the art to which the present invention pertains. Therefore, the present invention is not be limited to the exemplary embodiments set forth herein but may be modified in many different forms. In the drawings, the size and the thickness of the apparatus may be exaggerated for convenience. Like reference numerals denote like elements throughout the specification.

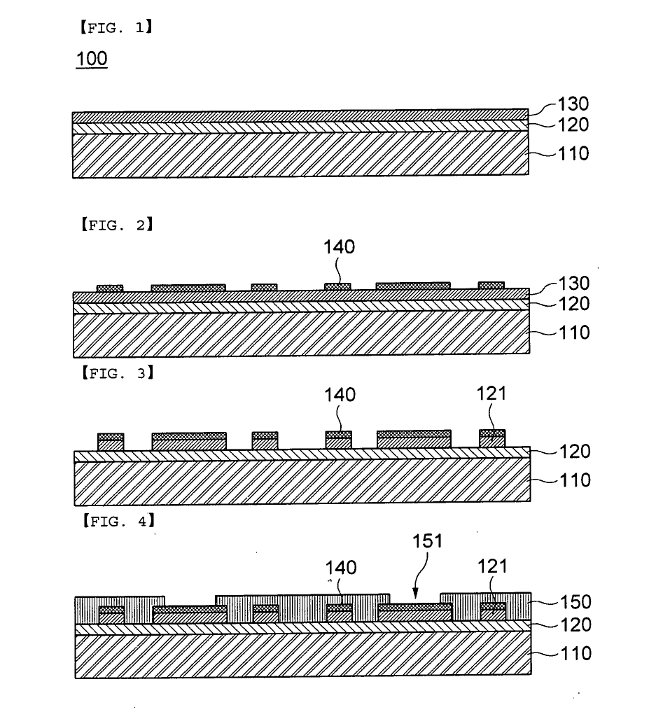

FIGS. 1 to 4 are cross sectional views for explaining a process of manufacturing a printed circuit board according to an exemplary embodiment of the present invention.

Referring to FIG. 1, in order to manufacture a printed circuit board, a base substrate 100 including a conductive layer provided on at least one surface thereof is first provided.

Herein, the base substrate 100 may include a heat radiating layer 110, an insulating layer 120 disposed on the heat radiating layer 110, and a conductive layer 130 disposed on the insulating layer 120.

The heat radiating layer 110 may be made of a metal, for example, one selected from a group consisting of aluminum, silver, copper, iron, chrome, and magnesium or at least one alloy thereof. Herein, the heat radiating layer 110 may effectively radiate heat generated from an electronic component to the outside.

The insulating layer 120 may electrically insulate the heat radiating layer 110 from the conductive layer 130. The insulating layer 120 may be made of a metal oxide configuring the heat radiating layer 110. At this time, the insulating layer 120 may be formed by anodizing a surface of the heat radiating layer 110. However, the exemplary embodiment of the present invention is not limited thereto. For example, the insulating layer 120 may be also formed by applying a separate insulating resin or attaching an insulating film on the heat radiating layer 110.

The conductive layer 130, which is a base material for forming a circuit wiring 150 described below, may be formed at a thickness thinner than that of the designed circuit wiring 150. This is the reason that although the thickness of the conductive layer 130 is formed to be thinner than that of the designed circuit wiring 150, it may be sufficiently compensated by conductive resist patterns 140 described below.

The conductive layer 130 may be made of copper, but the exemplary embodiment of the present invention is not limited thereto.

Although not shown in the drawings, an adhesive layer, for example, prepreg is further provided between the conductive layer 130 and the insulating layer 120, thereby making it possible to stably bond the conductive layer 130 on the heat radiating layer 110.

Although the exemplary embodiment of the present invention describe the case in which the base substrate 100 includes the insulating layer 120 and the conductive layer 130 provided on one surface of the heat radiating layer 110, the present invention is not limited thereto. For example, the base substrate 100 may include the insulating layers 120 and the conductive layers 130 provided on both surfaces of the heat radiating layer 110.

Although the exemplary embodiment of the present invention describe that the base substrate 100 includes the heat radiating layer 110, the present invention is not limited thereto but the base substrate 100 may include only an insulating layer. At this time, the insulating layer may be made of an epoxy resin impregnated into a glass fiber or ceramic.

Referring to FIG. 2, after the base substrate 100 is provided, the conductive resist patterns 140 are formed on the conductive layer 130 of the base substrate 100.

Herein, the conductive resist pattern 140 may be formed by printing a conductive paste on the conductive layer 130. At this time, the conductive paste may be made of a material having a different etching selectivity from that of the conductive layer 130, for example, a silver (Ag) paste.

In addition, the printing of the conductive paste may be performed using a screen printing method. As examples of other methods for printing the conductive paste, an offset printing method, a reverse offset printing method, a gravure printing, or the like, may be used.

The conductive resist pattern 140 may be formed at a thin thickness, for example, a thickness in the range of 3 μm to 15 μm, so that etchant may be easily penetrated to the lower portion of the conductive resist pattern 140 during an etching process described below. At this time, when the thickness of the conductive resist pattern 140 is below 3 μm, the conductive resist pattern may not be used as an etching mask due to the excessively thin thickness thereof. In addition, when the thickness of the conductive resist pattern 140 exceeds 15 μm, it is difficult to accomplish the purpose for allowing easy permeation of the etchant to the lower portion of the conductive resist pattern 140, thereby having a difficulty in implementing fine circuit wiring patterns.

Referring to FIG. 3, after the conductive resist patterns 140 are formed, the circuit wirings 150 may be formed by etching the conductive layer 130 using the conductive resist patterns 140 as the etching mask.

When the conductive layer 130 is made of copper, the conductive layer 130 may be etched through a wet etching using etchant, for example, copper chloride solution or iron chloride solution. At this time, as the conductive resist pattern 140 is made of silver paste, it may have etching resistance to the copper chloride solution or the iron chloride solution, thereby being used as the etching mask in the wet etching process.

The conductive resist pattern 140, which is the etching mask, may be formed at a thinner thickness as compared to the case in which the dry film according to the related art is used. Therefore, the etchant may be easily penetrated between the conductive resist patterns 140 corresponding to a space width between the circuit wirings 150 described below, thereby making it possible to prevent etching defects. Accordingly, when designing the space width between the circuit wirings 150, there is no need to consider whether or not the etchant is penetrated. The reason is that when designing the space width between the circuit wirings 150 is that in the case in which the thickness of the conductive paste 140 is thick and the space between the designed circuit wirings 150 is narrow, it is difficult to permeate the etchant between the circuit wirings 150, thereby having a limitation in narrowing the space between the circuit wirings 150.

The conductive layer 130 is formed to be thinner than the designed value, thereby making it possible to shorten an etching process time as compared to the conductive layer 130 having the thickness with an existing designed value. In addition, as the thickness of the conductive layer 130 is lowered, the occurrence of an undercut during the wet etching process can be reduce, thereby making it possible to implement a fine circuit wiring pattern.

After the circuit wiring 150 is formed, the conductive resist pattern 140 may be disposed on the circuit wiring 150 to serve as the circuit wiring 150. That is, the conductive resist pattern 140 may serve to compensate for the thickness of the designed circuit wiring 150.

Referring to FIG. 4, after the circuit wiring 150 is formed, a solder resist 160 is formed on the conductive resist pattern 140.

The solder resist 160 may be formed on the base substrate 100 including the conductive resist pattern 140 through an applying method or a laminating method. In addition, the solder resist 160 may be formed with an opening exposing a pad. Herein, the opening may be formed in the solder resist 160 applied or laminated on the base substrate 100 through an exposure process or a development process.

Accordingly, in the exemplary embodiment of the present invention, as the conductive resist pattern formed by printing the conductive paste is used as the etching mask, it may also function as the circuit wiring to lower the thickness of the conductive layer for forming the circuit wiring, thereby making it possible to reduce the etching process time of the conductive layer.

In addition, the conductive resist pattern is formed through the screen printing method, such that the thickness of the conductive resist pattern becomes thinner than the dry film according to the related art, thereby making it possible to implement the fine circuit wiring pattern.

In addition, there is no need to use a separate expensive dry film in order to form the fine circuit wiring pattern, thereby making it possible to reduce the manufacturing cost of the printed circuit board.

In addition, the printed circuit board according to the exemplary embodiment of the present invention includes the heat radiating layer therein, thereby making it possible to expect a heat radiating effect.

A printed circuit board manufactured through a method of manufacturing a printed circuit board according to the exemplary embodiment of the present invention will be described in detail with reference to FIG. 4.

Referring to FIG. 4, a printed circuit board according to an exemplary embodiment of the present invention may include a base substrate 100, a circuit wiring 150 disposed on the base substrate 100 and a conductive resist pattern 140 disposed on the circuit wiring 150.

Herein, the conductive resist pattern 140 may be made of a conductive paste including a material having a different etching selectivity from that of the circuit wiring 150, for example, a silver (Ag) paste. At this time, the circuit wiring 150 may be made of copper.

The conductive resist pattern 140 may serve to compensate for a thickness of the circuit wiring 150, while being used as an etching mask for forming the circuit wiring 150. Accordingly, the conductive resist pattern 140 and the circuit wiring 150 may have shapes corresponding to each other.

The base substrate 100 may include a heat radiating layer 110 and an insulating layer disposed on the heat radiating layer 110.

The heat radiating layer 110 may be made of a metal, for example, one selected from a group consisting of aluminum, silver, copper, iron, chrome, and magnesium or at least one alloy thereof. Herein, the heat radiating layer 110 may effectively radiate heat generated from an electronic component mounted on the printed circuit board to the outside.

The insulating layer 120 may electrically insulate the heat radiating layer 110 from the circuit wiring 150. The insulating layer 120 may be made of a metal oxide configuring the heat radiating layer 110. At this time, the insulating layer may be formed by anodizing a surface of the heat radiating layer. However, the exemplary embodiment of the present invention is not limited thereto. For example, the insulating layer 120 may also be formed by applying a separate insulating resin or attaching an insulating film on the heat radiating layer 110.

Although the exemplary embodiment of the present invention describes the case in which the base substrate includes the printed circuit provided on one surface thereof, the present invention is not limited thereto. For example, the base substrate may also include a multi-layer circuit wiring or the printed circuits on both surfaces thereof.

In addition, although the exemplary embodiment of the present invention describes the case in which the base substrate 100 includes the heat radiating layer 110, the present invention is not limited thereto 120. The base substrate 100 may include only the insulating layer. At this time, the insulating layer 120 may be made of an epoxy resin impregnated into a glass fiber or ceramic.

In addition, a solder resist 160 may further be provided on the base substrate 100 including the conductive resist patterns 140.

As set forth above, the printed circuit board according to the exemplary embodiments of the present invention uses the conductive resist pattern formed by printing the conductive paste as the etching mask, such that the conductive resist pattern may also serve as the circuit wiring to lower the thickness of the conductive layer for forming the circuit wiring, thereby making it possible to reduce the etching process time of the conductive layer.

In addition, the printed circuit board according to the exemplary embodiments of the present invention forms the conductive resist pattern through screen printing, such that the thickness of the conductive resist pattern becomes thinner than the dry film according to the related art, thereby making it possible to implement the fine circuit wiring pattern.

In addition, the printed circuit board according to the exemplary embodiments of the present invention does not to separately use an expensive dry film, thereby making it possible to reduce the manufacturing cost of the printed circuit board.

In addition, the printed circuit board according to the exemplary embodiment of the present invention includes the heat radiating layer therein, thereby making it possible to expect a heat radiating effect.

What is claimed is:

1. A method of manufacturing a printed circuit board, comprising:
providing a base substrate including a conductive layer provided on at least one surface thereof;
forming conductive resist patterns by printing a conductive paste on the conductive layer;
forming circuit wirings by etching the conductive layer using the conductive resist patterns as an etching mask; and
forming a solder resist on the circuit wiring.

2. The method of manufacturing a printed circuit board according to claim 1, wherein the base substrate includes:
a heat radiating layer;
an insulating layer disposed on the heat radiating layer; and
a conductive layer disposed on the insulating layer.

3. The method of manufacturing a printed circuit board according to claim 2, wherein the heat radiating layer is made of a metal and the insulating layer is made of a metal oxide.

4. The method of manufacturing a printed circuit board according to claim 2, further comprising interposing an adhesive layer between the insulating layer and the conductive layer.

5. The method of manufacturing a printed circuit board according to claim 1, wherein the conductive paste has a different etching selectivity from that of the conductive layer.

6. The method of manufacturing a printed circuit board according to claim 1, wherein the conductive resist pattern is made of a silver (Ag) paste.

7. The method of manufacturing a printed circuit board according to claim 1, wherein the conductive resist pattern is formed at a thickness in the range of 3 μm to 15 μm.

8. A printed circuit board, comprising:
circuit wirings formed on a base substrate;
conductive resist patterns disposed on the circuit wirings; and
a solder resist disposed on the base substrate including the conductive resist patterns.

9. The printed circuit board according to claim 8, wherein the base substrate includes:
a heat radiating layer; and
an insulating layer disposed on the heat radiating layer.

10. The printed circuit board according to claim 9, further comprising an adhesive layer interposed between the insulating layer and the circuit wiring.

11. The printed circuit board according to claim 9, wherein the heat radiating layer is made of a metal and the insulating layer is made of a metal oxide.

12. The printed circuit board according to claim 8, wherein the conductive resist pattern is made of a silver (Ag) paste.
